(19) United States
(12) Patent Application Publication
(10) Pub. No.: US 2026/0293298 A1
(43) Pub. Date: Sep. 24, 2026

(54) SEMICONDUCTOR DEVICE

(71) Applicant: SAMSUNG ELECTRONICS CO., LTD., Suwon-si (KR)

(72) Inventors: Junseong SONG, Suwon-si (KR); Yonghyun KWON, Suwon-si (KR); Kyuhwan SIM, Suwon-si (KR); GyuHyun LEE, Suwon-si (KR); Sangmin JEONG, Suwon-si (KR); Gyuhyun KIL, Suwon-si (KR); Hyun-Seung KIM, Suwon-si (KR); Doosan BACK, Suwon-si (KR); Hong-Woo SEO, Suwon-si (KR); Jung-Hoon HAN, Suwon-si (KR)

(73) Assignee: SAMSUNG ELECTRONICS CO., LTD., Suwon-si (KR)

(21) Appl. No.: 19/396,474

(22) Filed: Nov. 21, 2025

(30) Foreign Application Priority Data
Mar. 21, 2025 (KR) 10-2025-0036704

(51) Int. Cl. H10D 84/83; H10B 12/00; H10D 30/01; H10D 62/832; H10D 64/66; H10D 84/01

(52) U.S. Cl. CPC H10D 84/8314; H10D 62/832; H10D 64/669; H10D 84/8311; H10D 84/83135; H10B 12/50; H10D 30/027; H10D 84/014; H10D 84/0144; H10D 84/0151

(57) ABSTRACT

A semiconductor device including a semiconductor substrate including a first active region and a second active region, a first source/drain region provided in the first active region, a second source/drain region provided in the second active region, a first gate structure on the first active region, a semiconductor layer having a lattice constant different from the semiconductor substrate on the second active region, and a second gate structure on the semiconductor layer, wherein the first source/drain region includes a first lower portion and a first upper portion on the first lower portion, wherein the first lower portion includes a first sidewall facing the second source/drain region, and wherein the first upper portion includes a second sidewall connected to the first sidewall of the first lower portion and inclined with the first sidewall.

### CROSS-REFERENCE TO RELATED APPLICATIONS

This U.S. non-provisional patent application claims priority under 35 U.S.C. § 119 to Korean Patent Application No. 10-2025-0036704, filed on Mar. 21, 2025, in the Korean Intellectual Property Office, the entire contents of which are hereby incorporated by reference.

### BACKGROUND

The present disclosure relates to a semiconductor device, and in particular, to a semiconductor device including transistors with different threshold voltages.

A semiconductor device includes an integrated circuit consisting of metal-oxide-semiconductor field-effect transistors (MOS-FETs). As an integration density of the semiconductor device increases, the MOS-FETs are being gradually scaled down, but this leads to deterioration in operation characteristics of the semiconductor device. Accordingly, various studies have been conducted to overcome technical limitations associated with scale-down of the semiconductor device and to realize high-performance semiconductor devices.

### SUMMARY

An embodiment of the inventive concept provides a semiconductor device having improved electrical characteristics and reliability.

According to an embodiment of the inventive concept, a semiconductor device may comprise a semiconductor substrate including a first active region and a second active region, a first source/drain region provided in the first active region, a second source/drain region provided in the second active region, a first gate structure on the first active region, a semiconductor layer having a lattice constant different from the semiconductor substrate on the second active region, and a second gate structure on the semiconductor layer, wherein the first source/drain region includes a first lower portion and a first upper portion on the first lower portion, wherein the first lower portion includes a first sidewall facing the second source/drain region, and wherein the first upper portion includes a second sidewall connected to the first sidewall of the first lower portion and inclined with the first sidewall.

According to an embodiment of the inventive concept, a semiconductor device may comprise a semiconductor substrate including a first active region and a second active region, and a third active region sequentially disposed along a first direction, a first source/drain region provided in the first active region, a second source/drain region provided in the second active region, a third source/drain region provided in the third active region, a first gate structure on the first active region, a second gate structure on the second active region, a third gate structure on the third active region, and a semiconductor layer between the second active region and the second gate structure, wherein the first source/drain region comprises a first lower portion and a first upper portion on the first lower portion, wherein the third source/drain region comprises a second lower portion and a second upper portion on the second lower portion, wherein a sidewall of the first upper portion is inclined with a sidewall of the first lower portion, wherein a sidewall of the second upper portion is inclined with a sidewall of the second lower portion, and wherein the semiconductor layer includes silicon-germanium (SiGe).

According to an embodiment of the inventive concept, a semiconductor device may comprise a semiconductor substrate including a cell array region and a peripheral circuit region, the peripheral circuit region including a first active region and a second active region, a device isolation layer defining a cell active region on the cell array region, the first active region, and the second active region, a bit line structure crossing the cell active region on the cell array region, a first source/drain region provided in the first active region, a second source/drain region provided in the second active region, a first gate structure on the first active region, a semiconductor layer having a lattice constant different from a lattice constant of the semiconductor substrate and disposed on the second active region, and a second gate structure on the semiconductor layer, wherein the first source/drain region comprises a first lower portion and a first upper portion on the first lower portion, wherein the first lower portion includes a first sidewall facing the second source/drain region, and wherein the first upper portion includes a second sidewall connected to the first sidewall of the first lower portion and inclined with the first sidewall.

According to an embodiment of the inventive concept, a method of manufacturing a semiconductor device may include providing a semiconductor substrate including first and second active regions, forming a device isolation layer covering the first and second active regions, selectively etching the device isolation layer to expose a top surface of the second active region, forming a semiconductor layer on the second active region; forming a capping insulating layer conformally covering the semiconductor layer, selectively etching the device isolation layer to expose a top surface of the first active region, and performing an oxidation process on the first active region and the capping insulating layer to form an insulating layer.

In some embodiments, the method of manufacturing the semiconductor device may further comprise selectively removing the insulating layer disposed on the semiconductor layer to form an insulating pattern after forming the insulating layer; and removing the capping insulating layer to expose the semiconductor layer.

In some embodiments, the method of manufacturing the semiconductor device may further comprise forming a first gate structure on the insulating pattern after exposing the semiconductor layer; and forming a second gate structure on the semiconductor layer.

In some embodiments, performing the oxidation process may be performed at a temperature ranged about 700° C. to 1100° C.

In some embodiments, performing the oxidation process to form an insulating layer may include oxidizing a portion of the first active region.

In some embodiments, the insulating layer and the semiconductor layer may be spaced apart from each other during performing the oxidation process to form an insulating layer.

### BRIEF DESCRIPTION OF THE DRAWINGS

FIG. 1 is a plan view illustrating a semiconductor device according to embodiments of the inventive concept.

FIG. 2 is a cross-sectional view of a semiconductor device according to embodiments of the inventive concept, which is taken along lines A-A′ and B-B′ of FIG. 1.

FIG. 3A is an enlarged view of a P1 portion of FIG. 2.

FIG. 3B is an enlarged view of a semiconductor device according to some embodiments of the inventive concept, and corresponds to FIG. 3A.

FIG. 4 is a cross-sectional view of a semiconductor device according to embodiments of the inventive concept, which is taken along lines B-B′ and C-C′ of FIG. 1.

FIG. 5 is an enlarged view of a P2 portion of FIG. 4.

FIGS. 6, 7, 8, 9, 10, 11, 12, 13 and 14 are diagrams illustrating a method of manufacturing a semiconductor device according to some embodiments of the inventive concept.

FIG. 15 is a plan view illustrating a semiconductor device according to embodiments of the inventive concept.

FIG. 16 is a cross-sectional view of a semiconductor device according to embodiments of the inventive concept, which is taken along lines I-I′, II-II′, and III-III′ of FIG. 15.

### DETAILED DESCRIPTION

Hereinafter, a semiconductor device according to embodiments of the inventive concept will be described in detail with reference to the drawings.

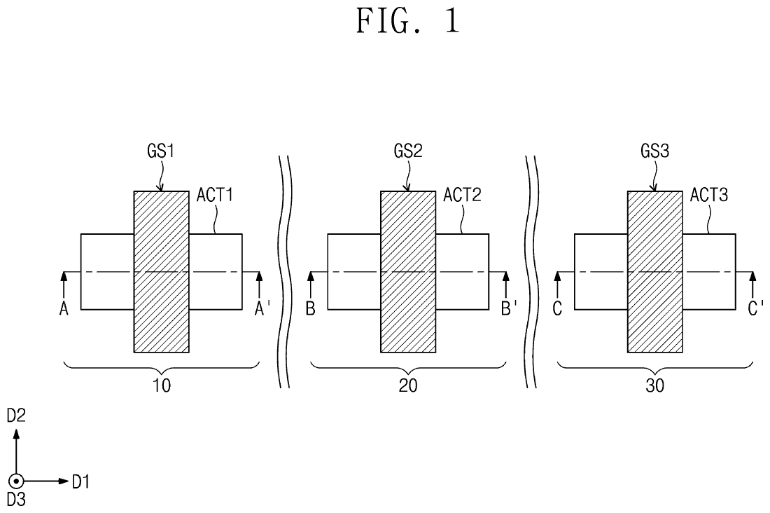

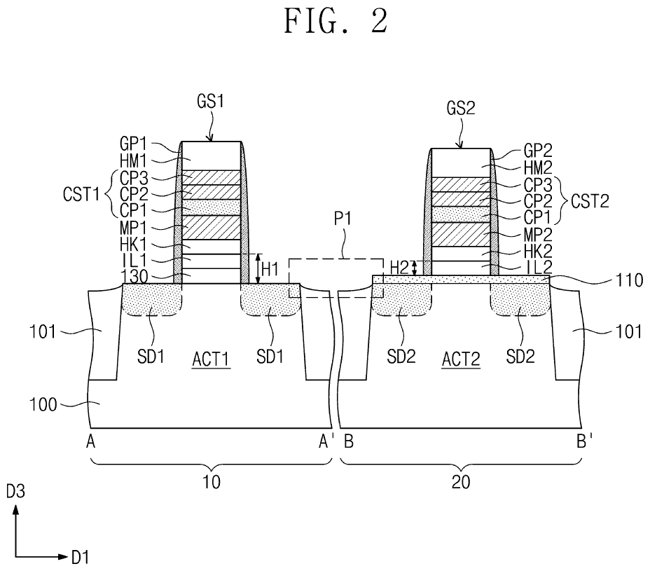

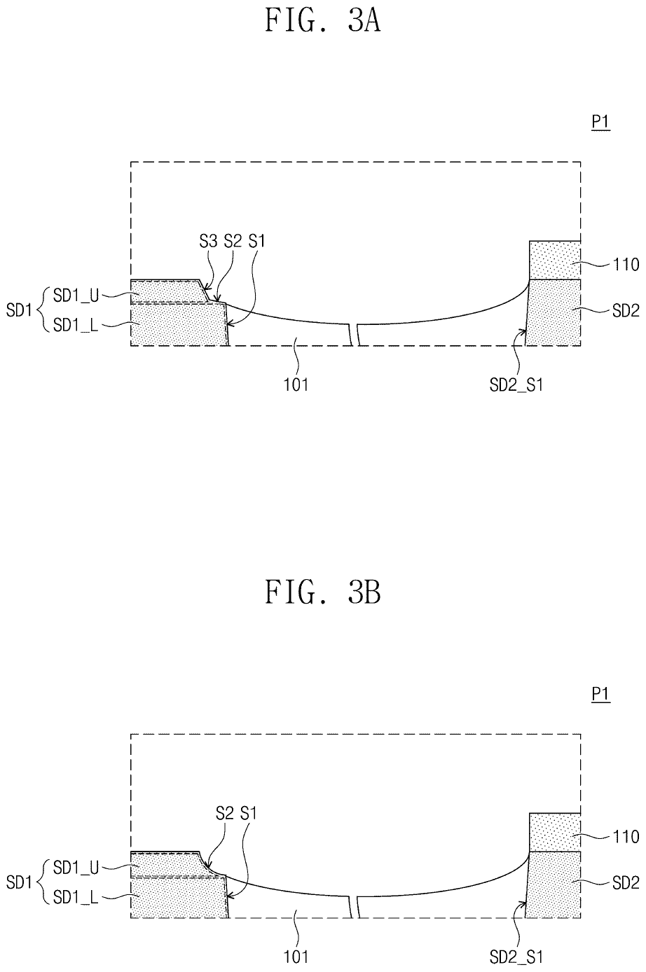

FIG. 1 is a plan view illustrating a semiconductor device according to embodiments of the inventive concept. FIG. 2 is a cross-sectional view of a semiconductor device according to embodiments of the inventive concept, which is taken along lines A-A′ and B-B′ of FIG. 1. FIG. 3A is an enlarged view of a P1 portion of FIG. 2.

Referring to FIGS. 1 and 2, a semiconductor substrate 100 including first to third regions 10, 20, 30 may be provided. A first active region ACT1 may be disposed in the first region 10, a second active region ACT2 may be disposed in the second region 20, and a third active region ACT3 may be disposed in the third region 30.

For example, logic transistors configuring a logic circuit may be disposed on the semiconductor substrate 100. For another example, the semiconductor device may be a dynamic random access memory (DRAM) including a cell capacitor.

The semiconductor substrate 100 may be a single crystalline silicon wafer, but in an embodiment, the semiconductor substrate 100 may be a silicon-on-insulator (SOI) wafer, a germanium wafer, a germanium-on-insulating (GOI) wafer, a silicon-germanium substrate, or a substrate including an epitaxial layer formed by a selective epitaxial growth (SEG) process. In an embodiment, the semiconductor substrate 100 may include an n-type or p-type well impurity layer.

In embodiments, a first transistor may be provided on the first region 10, a second transistor may be provided on the second region 20, and a third transistor may be provided on the third region 30. A PMOS transistor may be provided on the second region 20, and an NMOS transistor may be provided on the third region 30. For example, an NMOS transistor may be provided on the first region 10, and for another example, a PMOS transistor may be provided on the first region 10. For example, the second transistor may have a different threshold voltage form the first and third transistors. For another example, the third transistor may have a different threshold voltage from the first and second transistors.

Specifically, a device isolation layer 101 may be disposed in the semiconductor substrate 100. The device isolation layer 101 may define the first active region ACT1, the second active region ACT2, and the third active region ACT3. The device isolation layer 101 may have a top surface recessed toward the semiconductor substrate 100. The first to third active regions ACT1, ACT2, ACT3 may be spaced apart from each other along the first direction D1. In the present specification, the first direction D1 and the second direction D2 may refer directions parallel to the bottom surface of the semiconductor substrate 100 and may intersect with each other. The third direction D3 may intersect the first and second directions D1 and D2, and refer a direction perpendicular to the bottom surface of the semiconductor substrate 100.

A first gate structure GS1 may be disposed on the first active region ACT1. A first source/drain region SD1 may be provided in the semiconductor substrate 100 on both sides of the first gate structure GS1, respectively. For example, the first source/drain region SD1 may be portions of the semiconductor that are doped with impurities of a first conductivity type (e.g., n-type). For another example, the first source/drain region SD1 may be a portion of the semiconductor that are doped with impurities of a second conductivity type (e.g., p-type).

A second gate structure GS2 may be disposed on the second active region ACT2. A second source/drain region SD2 may be provided in the semiconductor substrate 100 on both sides of the second gate structure GS2, respectively. The second source/drain region SD2 may be a portion of the semiconductor that are doped with the impurities of the second conductivity type (e.g., p-type). The second source/drain regions SD2 may be provided in the channel layer 110 that vertically overlaps the second source/drain region SD2 (not shown).

In embodiments, the first gate structure GS1 may include an insulating pattern 130, a first interface pattern IL1, a first high-k dielectric pattern HK1, a first metal pattern MP1, a first conductive structure CST1, a first hard mask pattern HM1, and first gate spacers GP1.

The insulating pattern 130 may be disposed on the first active region ACT1 and disposed between the first interface pattern IL1 and the semiconductor substrate 100. The insulating pattern 130 may include, for example, silicon oxide, silicon oxynitride, silicon nitride, or a combination thereof. In embodiments, the insulating pattern 130 may be disposed in the first gate structure GS1 on the first active region ACT1, but not in the second gate structure GS2 on the second active region ACT2.

The first interface pattern IL1 may be disposed between the first high-k dielectric pattern HK1 and the insulating pattern 130. The first interface pattern IL1 may include, for example, silicon oxide, silicon oxynitride, silicon nitride, or a combination thereof.

The first high-k dielectric pattern HK1 may be disposed between the first interface pattern IL1 and the first metal pattern MP1. The first high-k dielectric pattern HK1 may be formed of a high-k dielectric material having a dielectric constant greater than that of silicon oxide. The first high-k dielectric pattern HK1 may include metal oxides, metal silicates, or metal silicate nitrides. For example, the first high-k dielectric pattern HK1 may include oxides containing metallic element such as hafnium (Hf), aluminum (Al), lanthanum (La), or zirconium (Zr). The first high-k dielectric pattern HK1 may include hafnium silicate (HfSiO), zirconium silicate (ZrSiO), or a combination thereof. The first high-k dielectric pattern HK1 may include hafnium silicate nitride (HfSiON), zirconium silicate nitide (ZrSiON), or a combination thereof.

The first metal pattern MP1 may be disposed between the first high-k dielectric pattern HK1 and the first conductive structure CST1. The first metal pattern MP1 may be formed of a conductive material having a specific work function. The first metal pattern MP1 may have an N-type work function suitable for an NMOSFET. For example, the work function of the first metal pattern MP1 may be smaller than that of a second metal pattern MP2 to be described later. For example, the first metal pattern MP1 may include metal nitrides such as titanium nitride, tantalum nitride, tungsten nitride, hafnium nitride, and zirconium nitride. The metal pattern Mp1 may further include a lanthanoid material.

In some embodiments, the first metal pattern MP1 may have a P-type work function suitable for a PMOSFET. For another example, the first metal pattern MP1 may include metal nitrides such as titanium nitride, tantalum nitride, tungsten nitride, hafnium nitride, and zirconium nitride. The first metal pattern may further include a lanthanoid material and aluminum (Al).

The first conductive structure CST1 may include first to third conductive layers CP1, CP2, and CP3. The first to third conductive layers CP1, CP2, and CP3 may be sequentially stacked on the first metal pattern MP1.

The first conductive layer CP1 may include a conductive material different from the second conductive layer CP2 and the third conductive layer CP3. For example, the first conductive layer CP1 may include polysilicon. For example, the first conductive layer CP1 may include polysilicon doped with an impurity (e.g., an N-type impurity). The second conductive layer CP2 may be a barrier layer. The second conductive layer CP2 may be, for example, a TiSiN layer. The third conductive layer CP3 may be, for example, a tungsten (W) layer.

The first hard mask pattern HM1 may be disposed on the first conductive structure CST1. For example, the first hard mask pattern HM1 may include silicon nitride.

A pair of the first gate spacers GP1 may be disposed on both sidewalls of the first gate structures GS1, respectively.

In embodiments, the second gate structure GS2 may include a second interface pattern IL2, a second high-k dielectric pattern HK2, a second metal pattern MP2, a second conductive structure CST2, a second hard mask pattern HM2, and second gate spacers GP2.

A semiconductor layer 110 may be disposed on the second active region ACT2. The semiconductor layer 110 may be disposed between the second gate structure GS2 and the semiconductor substrate 100, particularly between the second interface pattern IL2 and the semiconductor substrate 100. The semiconductor layer 110 may not extend onto the first active region ACT1. That is, the semiconductor layer 110 may be provided on the second active region ACT2 and may not be provided on the first active region ACT1.

The semiconductor layer 110 may be formed by a selective epitaxial growth (SEG) process. The semiconductor layer 110 may include a semiconductor material having higher carrier mobility than silicon. The semiconductor layer 110 may have a lattice constant different from that of the semiconductor substrate 100. For example, the semiconductor layer 110 may be a silicon-germanium (SiGe) layer having a lattice constant different from that of the semiconductor substrate 100. For example, the semiconductor layer 110 may have a thickness of about 80 Å to 120 Å.

The second interface pattern IL2 may be disposed between the semiconductor layer 110 and the second high-k dielectric pattern HK2. The second interface pattern IL2 may include, for example, silicon oxide, silicon oxynitride, silicon nitride, or a combination thereof. For example, the second interface pattern IL2 may have substantially the same thickness as the first interface pattern IL1. As an example, the second interface pattern IL2 may include the same insulating material as the first interface pattern IL1. As used herein, the expression “substantially equal” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

The second high-k dielectric pattern HK2 may be disposed between the second interface pattern IL2 and the second metal pattern MP2. The second high-k dielectric pattern HK2 may be made of a high dielectric material having a dielectric constant greater than that of silicon oxide. The second high-k dielectric pattern HK2 may include, for example, metal oxides, metal silicates, or metal silicate nitrides. For example, the second high-k dielectric pattern HK2 may have substantially the same thickness as the first high-k dielectric patterns HK1, and may include the same metal element as the first high-k dielectric pattern HK1.

The second metal pattern MP2 may be disposed between the second high-k dielectric pattern HK2 and the second conductive structure CST2. The second metal pattern MP2 may be formed of a conductive material having a higher work function than the conductive material of the first metal pattern MP1. For example, the second metal pattern MP2 may include metal nitrides such as titanium nitride, tantalum nitride, tungsten nitride, hafnium nitride, and zirconium nitride, further including a lanthanoid material and aluminum (Al).

The second conductive structure CST2 may include first to third conductive layers CP1, CP2, CP3. The first to third conductive layers CP1, CP2, CP3 may be sequentially stacked on the second metal pattern MP2. The second conductive structure CST2 may include substantially the same materials as the first conductive structure CST1. That is, the first to third conductive layers CP1, CP2, CP3 of the second conductive structure CST2 may be substantially the same as the first to third conducting layers CP1, CP2 and CP3 of the first conductive structure CST1.

The second hard mask pattern HM2 may be disposed on the second conductive structure CST2. For example, the second hard mask pattern HM2 may include silicon nitride.

A pair of the second gate spacers GP2 may be disposed on both sidewalls of the second gate structures GS2, respectively.

In embodiments, the insulating pattern 130 may be provided on the first active region ACT1 and not on the second active region ACT2. Therefore, a vertical distance H1 between the first high-k dielectric pattern HK1 and the first active region ACT1 may be greater than a vertical distance H2 between the second high-k dielectric patterns HK2 and the semiconductor layer 110. The vertical distance H1 between the first high-k dielectric pattern HK1 and the first active region ACT1 may refer a sum of thicknesses of the insulating pattern 130 and the first interface pattern IL1 in the third direction D3. The vertical distance H2 between the second high-k dielectric patterns HK2 and the semiconductor layer 110 may refer a thickness of the second interface pattern IL2 in the third direction D3.

Referring to FIGS. 2 and 3A, the first source/drain region SD1 may include a first lower portion SD1_L and a first upper portion SD1_U. The first lower portion SD1_L may be in contact with the device isolation layer 101, and the first upper portion SD1_U may be spaced apart from the device isolation layer 101.

Specifically, the first lower portion SD1_L of the first source/drain region SD1 may have a first sidewall S1 facing the second source/drain region SD2. The first sidewall S1 may face one sidewall SD2_S1 of the second source/drain region SD2. At least a portion of the first sidewall S1 may be covered by the device isolation layer 101.

The first upper portion SD1_U of the first source/drain region SD1 may have a second sidewall S2 connected with the first sidewall S1. The second sidewall S2 may be inclined with the first sidewall S1. For example, the second sidewall S2 may form an obtuse angle with the first sidewall S1. The second sidewall S2 may be spaced apart from the device isolation layer 101.

The first upper portion SD1_U of the first source/drain region SD1 may further include a third sidewall S3 connected to the second sidewall S2. The third sidewall S3 may be inclined with the second sidewall S2. For example, the third sidewall S3 may form an obtuse angle with the second sidewall S2. The third sidewall S3 may be connected to a top surface of the first source/drain region SD1.

The one sidewall SD2_S1 of the second source/drain region SD2 may face the first sidewall S1 and the third sidewall S3 of the first source/drain region SD1. For example, the one sidewall SD2_S1 of the second source/drain region SD2 may be flat.

FIG. 3B is an enlarged view of a semiconductor device according to some embodiments of the inventive concept, and corresponds to FIG. 3A. In order to simplify the description, duplicate description will be omitted, and differences from the above will be mainly described.

Referring to FIG. 3B, the first upper portion SD1_U of the first source/drain region SD1 may have a second sidewall S2 connected to the first sidewall S1. For example, the second sidewall S2 may have a rounded shape. For example, the second sidewall S2 may refer a curved surface. The second sidewall S2 of the first upper portion SD1_U may be connected to the top surface of the first source/drain region SD1.

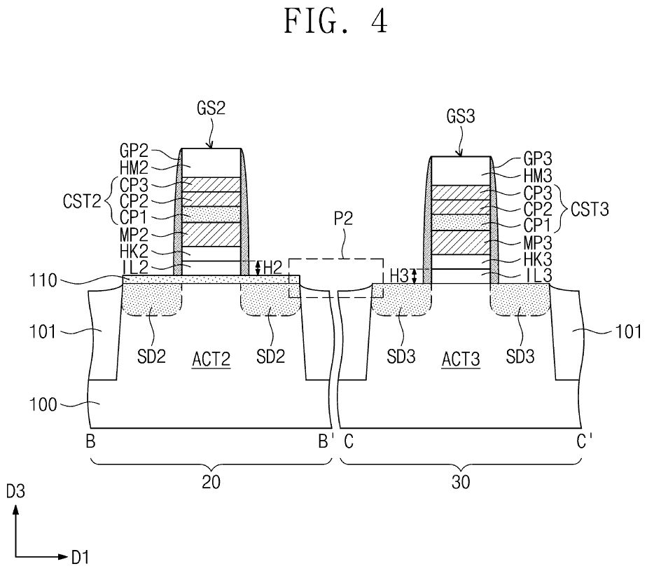

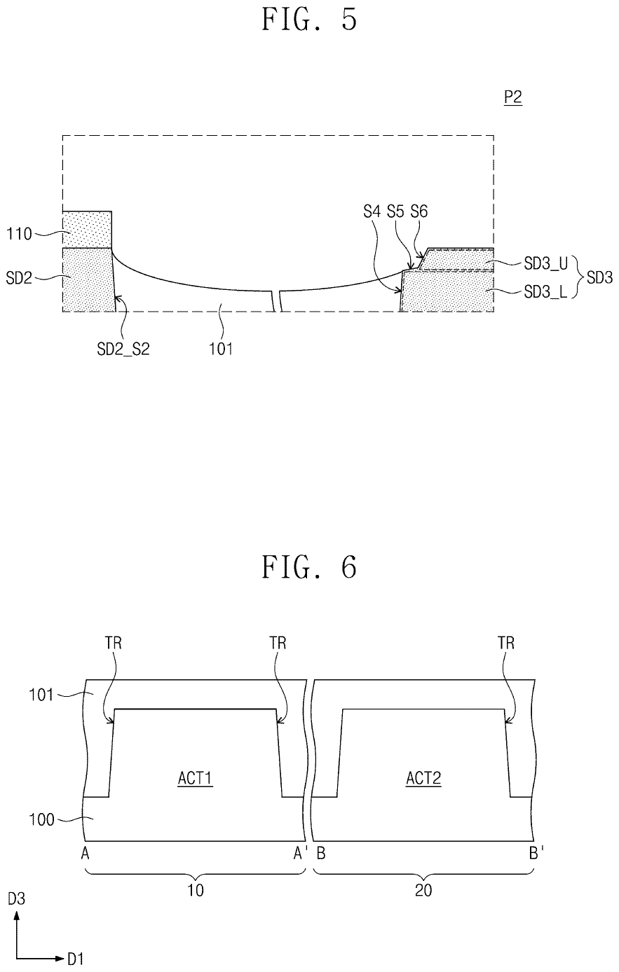

FIG. 4 is a cross-sectional view of a semiconductor device according to embodiments of the inventive concept, which is taken along lines B-B′ and C-C′ of FIG. 1. FIG. 5 is an enlarged view of a P2 portion of FIG. 4.

Referring to FIGS. 1 and 4, a third gate structure GS3 may be disposed on the third active region ACT3. A third source/drain region SD3 may be provided in the semiconductor substrate 100 on both sides of the third gate structure GS3. The third source/drain region SD3 may be a portion of the semiconductor that are doped with the impurities of the first conductivity type (e.g., n-type). The semiconductor layer 110 provided between the second gate structure GS2 and the second active region ACT2 may not extend onto the third active region ACT3. In other words, the semiconductor layer 110 may not be provided between the third gate structure GS3 and the third active region ACT3.

In embodiments, the third gate structure GS3 may include a third interface pattern IL3, a third high-k dielectric pattern HK3, a third metal pattern MP3, a third conductive structure CST3, a third hard mask pattern HM3, and third gate spacers GP3.

The third interface pattern IL3 may be disposed between the semiconductor substrate 100 and the third high-k dielectric pattern HK3 on the third active region ACT3. The third interface pattern IL3 may include, for example, silicon oxide, silicon oxynitride, silicon nitride, or a combination thereof. For example, the third interface pattern IL3 may have substantially the same thickness as the first interface pattern IL1. For example, the third interface pattern IL3 may include the same insulating material as the first interface pattern IL1.

The third high-k dielectric pattern HK3 may be disposed between the third interface pattern IL3 and the third metal pattern MP3. The third high-k dielectric pattern HK3 may be formed of a high dielectric material having a dielectric constant greater than that of silicon oxide. The third high-k dielectric pattern HK3 may include, for example, metal oxides, metal silicates, or metal silicate nitrides. For example, the third high-k dielectric pattern HK3 may have substantially the same thickness as the first high-k dielectric patterns HK1. The third high-k dielectric pattern HK3 may include the same metal element as the first high-k dielectric patterns HK1.

The third metal pattern MP3 may be disposed between the third high-k dielectric pattern HK3 and the third conductive structure CST3. The third metal pattern MP3 may be formed of a conductive material having a specific work function. The third metal pattern MP3 may have an N-type work function suitable for an NMOSFET. For example, the work function of the third metal pattern MP3 may be smaller than that of the second metal pattern MP2. For example, the third metal pattern MP3 may include metal nitride such as titanium nitride, tantalum nitride, tungsten nitride, hafnium nitride, and zirconium nitride and may further include a lanthanoid material.

The third conductive structure CST3 may include first to third conductive layers CP1, CP2, and CP3. The first to third conductive layers CP1, CP2, and CP3 may be sequentially stacked on the third metal pattern MP3. The third conductive structure CST3 may include substantially the same materials as the first conductive structure CST1. That is, the first to third conductive layers CP1, CP2, and CP3 of the third conductive structure CST3 may be substantially the same as the first to third conducting layers CP1, CP2 and CP3 of the first conductive structure CST1.

The third hard mask pattern HM3 may be disposed on the third conductive structure CST3. For example, the third hard mask pattern HM3 may include silicon nitride.

A pair of the third gate spacers GP3 may be disposed on both sidewalls of the third gate structures GS3, respectively.

In embodiments, the second interface pattern IL2 may be disposed between the second high-k dielectric pattern HK2 and the semiconductor layer 110, and the third interface pattern IL3 may be disposed between the third high-k dielectric patterns HK3 and the third active region ACT3. The vertical distance H2 (as shown in FIG. 2) between the second dielectric pattern HK2 and the semiconductor layer 110 may be substantially equal to a vertical distance H3 between the third dielectric pattern HK3 and the third active region ACT3. The vertical distance H2 between the second high-k dielectric pattern HK2 and the semiconductor layer 110 may refer the thickness of the second interface pattern IL2 in the third direction D3. The vertical distance H3 between the third high-k dielectric patterns HK3 and the third active region ACT3 may refer a thickness of the third interface pattern IL3 in the third direction D3.

Referring to FIGS. 4 and 5, the third source/drain region SD3 may include a second lower portion SD3_L and a second upper portion SD3_U. The second lower portion SD3_L may be in contact with the device isolation layer 101, and the second upper portion SD3_U may be spaced apart from the device isolation layer 101.

In detail, the second lower portion SD3_L of the third source/drain region SD3 may have a fourth sidewall S4 facing the second source/drain region SD2. At least a portion of the fourth sidewall S4 may be covered by the device isolation layer 101. The fourth sidewall S4 may face other sidewall SD2_S2 of the second source/drain region SD2. The other sidewall SD2_S2 of the second source/drain region SD2 may opposite the one sidewall SD2_S1 of the second source/drain region SD2 described above with reference to FIG. 3A.

The second upper portion SD3_U of the third source/drain region SD3 may have a fifth sidewall S5 connected with the fourth sidewall S4. The fifth sidewall S5 of the second upper portion SD3_U may be inclined with the fourth sidewall S4 of the second lower portion SD3_L. For example, the fifth sidewall S5 may form an obtuse angle with the fourth sidewall S4. The fifth sidewall S5 may be spaced apart from the device isolation layer 101.

The second upper portion SD3_U of the third source/drain region SD3 may further include a sixth sidewall S6 connected with the fifth sidewall S5. The sixth sidewall S6 may be inclined with the fifth sidewall S5. For example, the sixth sidewall S6 may form an obtuse angle with the fifth sidewall S5. The sixth sidewall S6 may be connected to a top surface of the third source/drain region SD3.

The other sidewall SD2_S2 of the second source/drain region SD2 may face the fourth sidewall S4 and the sixth sidewall S6 of the third source/drain regions SD3 along the first direction D1. For example, the other sidewall SD2_S2 of the second source/drain region SD2 may be flat.

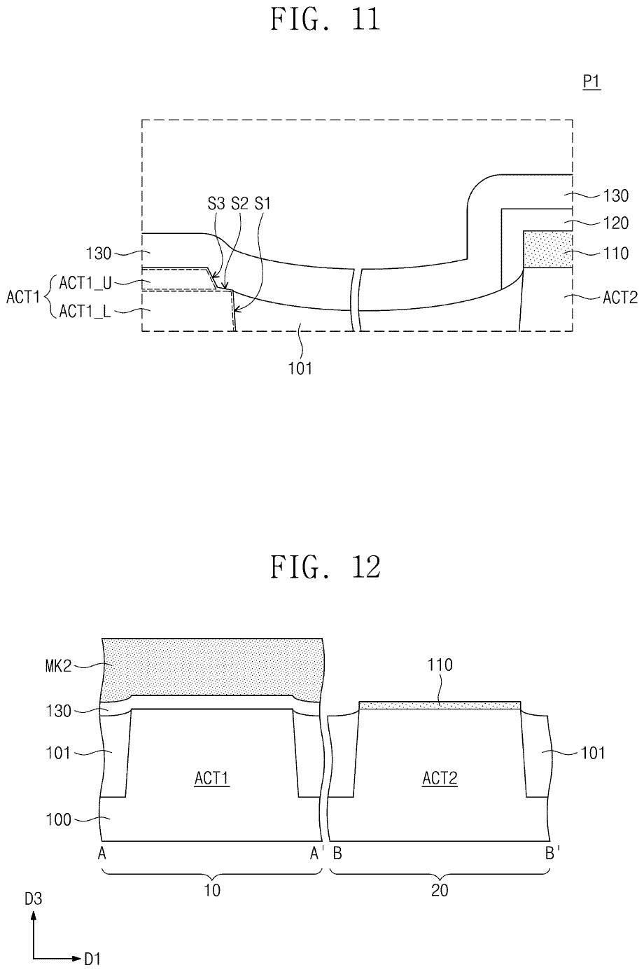

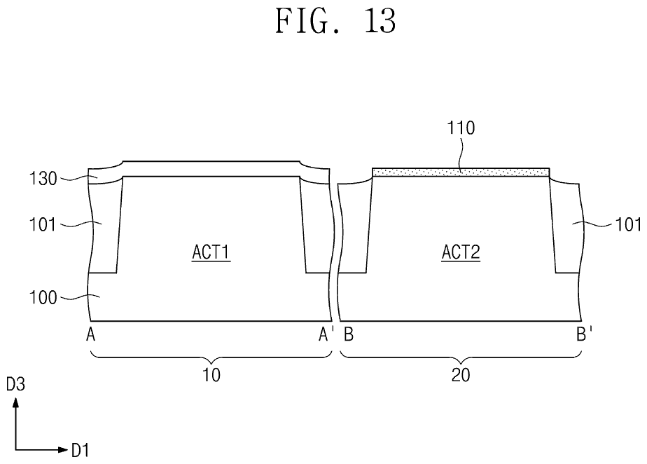

FIGS. 6 to 14 are diagrams illustrating a method of manufacturing a semiconductor device according to some embodiments of the inventive concept. Specifically, FIGS. 6 to 10 and 12-14 are cross-sectional views according to some embodiments of the inventive concept. FIG. 11 is an enlarged view according to some embodiments of the inventive concept.

Referring to FIG. 6, the semiconductor substrate 100 including the first and second regions 10, 20 may be provided.

The semiconductor substrate 100 may be a single crystalline silicon wafer, but in embodiments, the semiconductor substrate 100 may be a silicon-on-insulator (SOI) wafer, a germanium wafer, a germanium-on-insulating (GOI) wafer, or a silicon-germanium wafer, or a substrate including an epitaxial layer formed by a selective epitaxial growth (SEG) process. In an embodiment, the semiconductor substrate 100 may include an n-type or p-type well impurity layer.

The trenches TR may be formed by patterning the semiconductor substrate 100. The trench TR may be formed between the first region 10 and the second region 20. The device isolation layer 101 defining the first active region ACT1 and the second active region ACT2 in the semiconductor substrate 100 may be formed. A device isolation layer 101 may be formed by depositing an insulating layer filling the trenches TR.

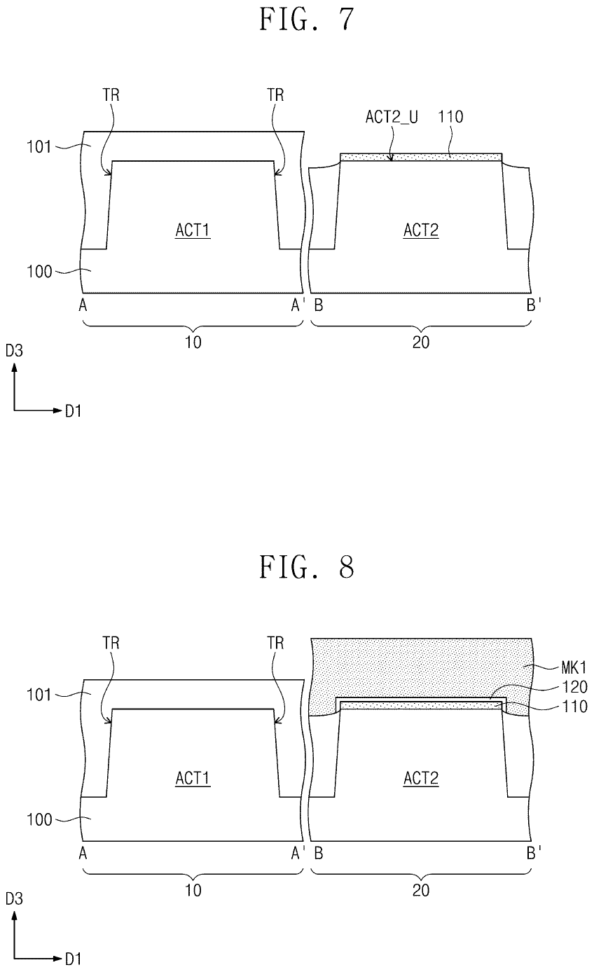

Referring to FIG. 7, a portion of the device isolation layer 101 may be removed to expose a top surface ACT2_U of the second active region ACT2 on the second region 20. The device isolation layer 101 on the first region 10 may not be removed, during removing the portion of the device isolation layer 101 on the second region 20.

On the second active region ACT2 of the second region 20, a semiconductor layer 110 may be formed by a selective epitaxial growth (SEG) process. The semiconductor layer 110 may include a semiconductor material having higher carrier mobility than silicon. For example, the semiconductor layer 110 may be a silicon-germanium (SiGe) layer having a lattice constant different from that of the semiconductor substrate 100.

Referring to FIG. 8, a capping insulating layer 120 may be formed on the semiconductor layer 110. The capping insulating layer 120 may conformally cover the semiconductor layer 110. The capping insulating layer 120 may be deposited on the semiconductor layer 110 and the device isolation layer 101. The capping insulating layer 120 may be connected to the device isolation layer 101 without an interface. The capping insulating layer 120 may include, for example, a silicon oxide layer and/or a silicon oxynitride layer. The capping insulating layer 120 may be formed by an atomic layer deposition (ALD) method, a chemical vapor deposition (CVD) method, and so on.

A first mask pattern MK1 may be formed on the second region 20. The first mask pattern MK1 may be disposed on the device isolation layer 101 on the second region 20. The first mask pattern MK1 may not cover the device isolation layer 101 on the first region 10. The first mask pattern MK1 may cover the capping insulating layer 120 and the semiconductor layer 110 on the second region 20.

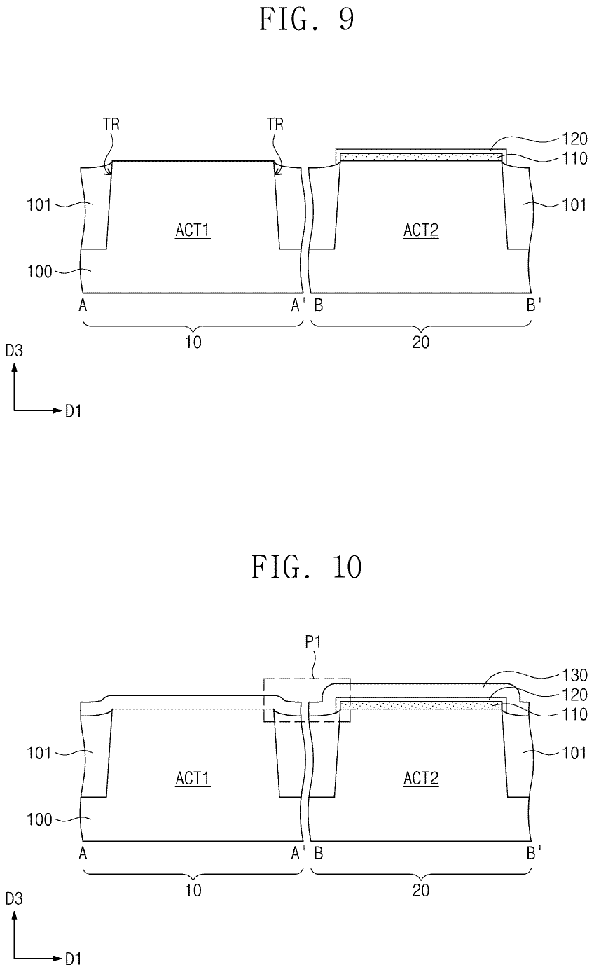

Referring to FIGS. 8 and 9, an etching process using the first mask pattern MK1 may be performed. Through the etching process, the device isolation layer 101 on the first region 10 can be partially removed. As the device isolation layer 101 on the first region 10 is partially removed, a top surface of the first active region ACT1 may be exposed to the outside. The device isolation layer 101 fills the trenches TR and may have a top surface recessed toward the semiconductor substrate 100. For example, the first mask pattern MK1 may be removed through the etching process. For another example, the first mask pattern MK1 may be removed through a separate removal process. Accordingly, the capping insulating layer 120 can be exposed to the outside.

Referring to FIG. 10, an insulating layer 130 may be formed on the first active region ACT1, the capping insulating layer 120, and the device isolation layer 101 through an oxidation process. For example, the oxidation process may be performed at a temperature ranged about 700° C. to 1100° C. The insulating layer 130 may conformally cover the first active region ACT1, the device isolation layer 101, and the capping insulating layer 120 on the first region 10 and the second region 20.

Referring to FIGS. 10 and 11, during the process of forming the insulating layer 130 through the oxidation process, a portion of the first active region ACT1 may be oxidized. During the oxidation process, the semiconductor layer 110 may be protected from being exposed to the outside by the capping insulating layer 120. That is, the semiconductor layer 110 may be protected during the oxidation process while being spaced apart from the insulating layer 130.

Specifically, the first active region ACT1 may include a lower portion ACT1_L in contact with the device isolation layer 101 and an upper portion ACT1_U spaced apart from the device isolation layer 101. A portion of the upper portion ACT1_U of the first active region ACT1 may be oxidized to form the insulating layer 130. Accordingly, the upper portion ACT1_U of the first active region ACT1 may include a recessed dent region.

In other words, the lower portion ACT1_L of the first active region ACT1 may have a first sidewall S1 facing the second active region ACT2. The upper portion ACT1_U of the first active region ACT1 may include a second sidewall S2 inclined with the first sidewall S1. The upper portion ACT1_U of the first active region ACT1 may further include a third sidewall S3 inclined with the second sidewall S2. The dent region of the upper portion ACT1_U of the first active region ACT1 may be defined by the second sidewall S2 and the third sidewall S3.

For example, in the case of forming the insulating layer 130 through a deposition process, the insulating layer 130 is formed at a relatively lower temperature than that of the oxidation process, and a defect may exist therein. Accordingly, the insulating layer 130 formed through the deposition may not be harder (or denser) than the insulating layer formed through the oxidation process. Furthermore, the insulating layer 130 formed through the deposition may not be formed to have a uniform thickness on an edge region (e.g., the second sidewall S2 or the third sidewall S3) of the first active region ACT1. For example, a thickness of the insulating layer 130 on the edge region of the first active region ACT1 may be smaller than a thickness of the insulation layer 130 on another region.

However, according to embodiments of the inventive concept, the insulating layer 130 formed through the oxidation process may have a more uniform thickness than that formed through the deposition process. Furthermore, the insulating layer 130 formed through the oxidation process may exhibit greater hardness (or density) than that formed through the deposition process. Accordingly, the insulating layer 130 may be formed to have a uniform thickness on the edge region (e.g., the second sidewall S2 or the third sidewall S3) of the first active region ACT1. That is, the overall quality of the insulating layer 130 may be improved. Therefore, the reliability of the insulating layer 130 may be improved in a subsequent process such as etching, and leakage current in transistor may be reduced. Furthermore, the electrical characteristics and reliability of the transistor can be improved.

Referring to FIG. 12, a second mask pattern MK2 may be formed on the first region 10. The second mask pattern MK2 covers the insulating layer 130 on the first region 10, and may not be provided on the second region 20.

An etching process using the second mask pattern MK2 may be performed to remove the capping insulating layers 120 and the insulating layer 130 on the second region 20. Therefore, a top surface of the semiconductor layer 110 and the top surface of a device isolation layer 101 may be exposed to the outside on the second region 20. In addition, the insulating layer 130 may be selectively removed on the second region 20, and the insulating layer 130 on the first region 10 may be referred to as an insulating pattern 130.

Referring to FIG. 13, the second mask pattern MK2 may be removed through a separate process. For another example, the second mask pattern MK2 may be removed together through the etching process described above with reference to FIG. 12. As the second mask pattern MK2 is removed, a top surface of the insulating pattern 130 may be exposed to the outside.

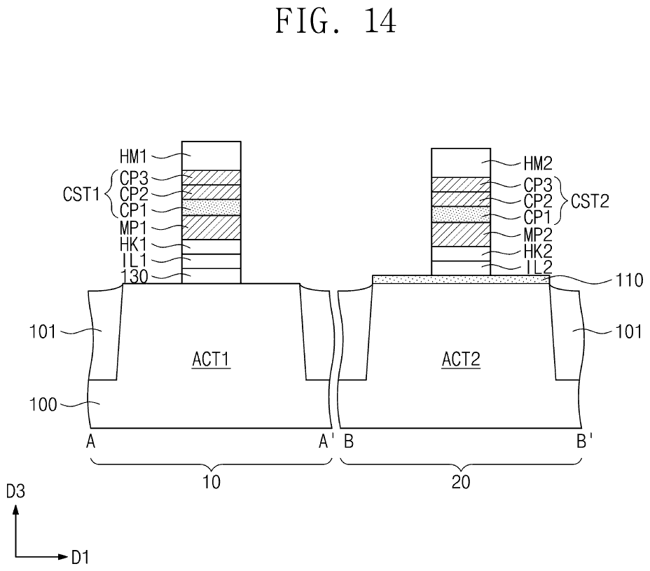

Referring to FIGS. 13 and 14, a first interface pattern IL1, a first high-k dielectric pattern HK1, a first metal pattern MP1, a first conductive structure CST1, and a first hard mask pattern HM1 may be formed on the insulating pattern 130 on the first region 10. A second interface pattern IL2, a second high-k dielectric pattern HK2, a second metal pattern MP2, a second conductive structure CST2, and a second hard mask pattern HM2 may be formed on the semiconductor layer 110 of the second region 20. The first and second conductive structures CST1 and CST2 may include first to third conductive layers CP1, CP2, and CP3, respectively.

Forming the first and second interface patterns IL1 and IL2, the first and second high-k dielectric patterns HK1 and HK2, the first and the second metal patterns MP1 and MP2, and the first and second conductive structures CST1 and CST2 may include forming an interface layer, forming a high-k dielectric layer, forming a metal layer, forming first to third conductive layers on the insulating pattern 130 and the semiconductor layer 110, and sequentially etching the interface layer, the high-k dielectric layer, the metal layer, and the first to third conductive layers using the first and second hard mask patterns HM1 and HM2 as an etching mask.

Referring back to FIG. 2, first gate spacers GP1 may be formed on both sidewalls of the insulating pattern 130, the first interface pattern IL1, the first high-k dielectric pattern HK1, the first metal pattern MP1, the first conductive structure CST1, and the first hard mask pattern HM1. As a result, a first gate structure GS1 may be formed.

Second gate spacers GP2 may be formed on both sidewalls of the second interface pattern IL2, the second high-k dielectric pattern HK2, the second metal pattern MP2, the second conductive structure CST2, and the second hard mask pattern HM2. Thus, a second gate structure GS2 may be formed.

First source/drain regions SD1 may be formed in the semiconductor substrate 100 on both sides of the first gate structure GS1 in the first region 10. Second source/drain regions SD2 may be formed in the semiconductor substrate 100 on both sides of the second gate structure GS2 in the second region 20.

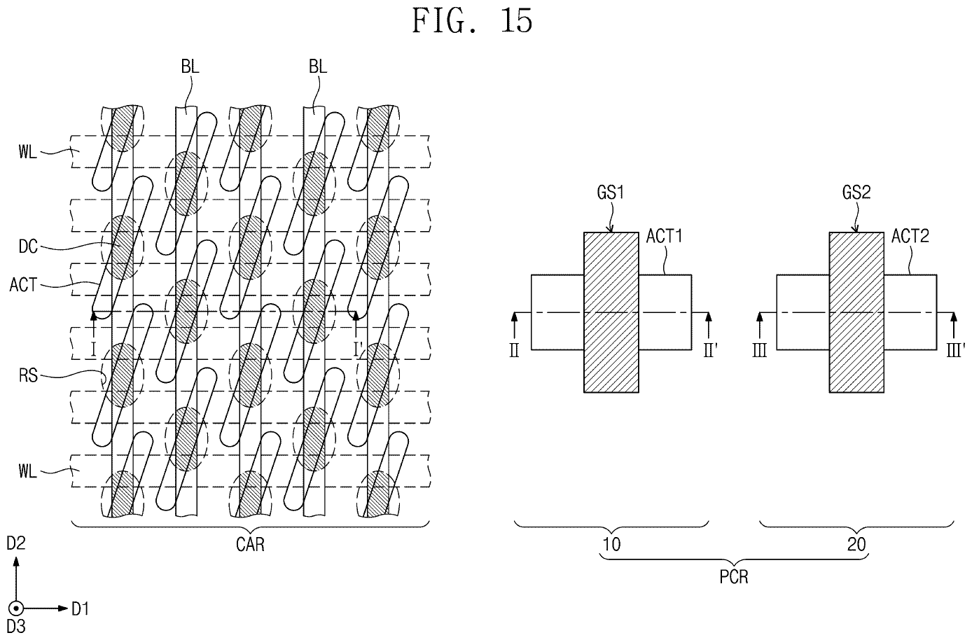

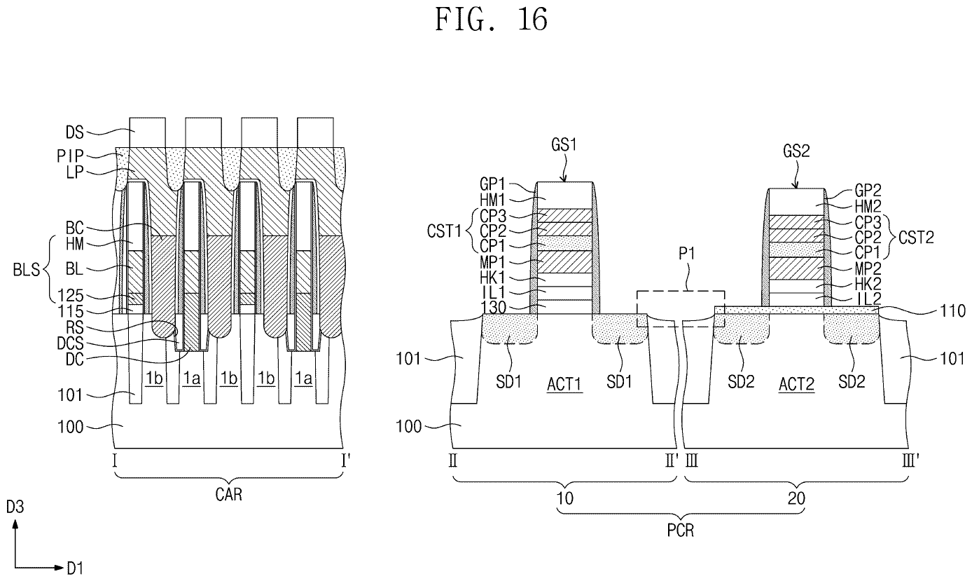

FIG. 15 is a plan view illustrating a semiconductor device according to embodiments of the inventive concept. FIG. 16 is a cross-sectional view of a semiconductor device according to embodiments of the inventive concept, which is taken along lines I-I′, II-II′, and III-III′ of FIG. 15. In order to simplify the description, duplicate description will be omitted, and differences from the above will be mainly described.

Referring to FIGS. 15 and 16, a semiconductor substrate 100 may include a cell array region CAR and a peripheral circuit region PCR, and the peripheral circuit region PCR may include a first region 10 and a second region 20.

Peripheral circuits for driving the word line WL and bit line BL disposed on the cell array region CAR may be disposed on the first region 10 and the second region 20. For example, an NMOS transistor may be provided on the first region 10, and a PMOS transistor may be provided on the second region 20.

More specifically, the device isolation layer 101 defining the cell active regions ACT may be disposed in the semiconductor substrate 100 on the cell array region CAR. The semiconductor substrate 100 may be a silicon wafer, a germanium wafer, and/or a silicon-germanium wafer, and so as on.

In some embodiments, the cell active regions ACT have a rectangular shape (or a bar shape) in a plan view, and may be two-dimensionally arranged along the first direction D1 and the second direction D2 perpendicular to the first direction D1, respectively. The cell active regions ACT may be arranged in a zigzag shape from a plan view, and may have a long axis along an inclined direction forming an acute angle with respect to the first direction D1 and the second direction D2.

Word line structures may extend in the first direction D1 across the cell active regions ACT in the semiconductor substrate 100. Each of the word line structures may include a word line WL, a gate insulating pattern between the semiconductor substrate 100 and the word line WL, and a gate capping pattern on the word line WL. The word line WL may include conductive material. The gate insulating pattern may include at least one of silicon oxide, silicon nitride, silicon oxynitride, or a high dielectric. The gate capping pattern may include, for example, silicon nitride or silicon oxynitride.

The word line WL may be disposed in the semiconductor substrate 100, and may extend along the first direction D1 in a plan view to cross the cell active regions ACT and the device isolation layer 101. Each of the cell active regions ACT may intersect a pair of word lines WL. A top surface of the word line WL may be located at a lower level than a top surface of the semiconductor substrate 100. A Bottom surface of the word line WL may differ in height depending on the material below them.

First and second impurity regions 1a, 1b may be formed in each of the cell active regions ACT on both sides of the word lines WL. Lower surfaces of the first and second impurity regions 1a, 1b may be located at a specific depth from the top surfaces of the cell active regions ACT. The first impurity region 1a may be disposed in each of the cell active regions ACT between the word lines WL. The second impurity region 1b may be disposed in end portions of each of the cell active regions ACT to be spaced apart from the first impurity region 1a. The first and second impurity regions 1a, 1b may be doped to have a conductivity type different from the semiconductor substrate 100.

A buffer insulating layer 115 may be provided on the semiconductor substrate 100. For example, the buffer insulating layer 115 may be formed of a single layer or multi-layer.

The bit line structures BLS may extend along the second direction D2 to across the word line WL on the semiconductor substrate 100. Each of the bit line structures BLS may be disposed on the first impurity region 1a. For example, each of the bit line structures BLS may include a polysilicon pattern 125 extending along the second direction D2, a bit line BL on the polysilicon patterns 125, and a hard mask pattern HM on the bit line BL. The buffer insulating layer 115 may be interposed between the polysilicon pattern 125 and the semiconductor substrate 100. A bit line contact pattern DC may be disposed between the bit line BL and the first impurity region 1a. The bit line contact pattern DC may be in contact with the first impurity region 1a. The bit line contact pattern DC may include polysilicon, and a silicide pattern may be interposed between the bit line contact pattern DC and the bit line BL. The silicide pattern may include at least one of titanium silicide, cobalt silicide, or nickel silicide. The bit line contact pattern DC may include conductive metal nitride (e.g., titanium nitride, tantalum nitride, etc.) and metal (e. g, tungsten, titanium, tantalium, etc.).

A bottom surface of the bit line contact pattern DC may be located at a level that is lower than the top surface of the semiconductor substrate 100 and is higher than the top surface of the word line WL. For example, the bit line contact pattern DC may be disposed locally in a recess region RS formed in the semiconductor substrate 100 and exposing the first impurity region 1a. For example, the recess region RS may have an elliptical shape.

The hard mask pattern HM in the bit line structures BLS may include an insulating material such as silicon nitride.

A bit line contact spacer DCS may fill the recess region RS in which the bit line contact pattern DC is formed. For example, the bit line contact spacer DCS may cover both sidewalls of the bit line contact pattern DC. For example, the bit line contact spacer DCS may include a silicon oxide layer, a silicon nitride layer, and/or a silicon oxynitride layer, and may be formed of multi-layer.

In embodiments, bit line spacers may be disposed on both sidewalls of the bit line structures BLS. The bit line spacers may extend in the second direction D2 along the bit line structures BLS. The bit line spacers may be disposed between the sidewalls of the bit line structures BLS and a buried contact pattern BC.

The buried contact pattern BC may be disposed between an adjacent pair of bit line structures BLS. The buried contact pattern BC may include an impurity doped polysilicon or metallic material. The buried contact pattern BC may be in contact directly with the second impurity region 1b, respectively. The buried contact pattern BC may be disposed between the word lines WL and between the bit line structures BLS, respectively, in a plan view.

The buried contact pattern BC may be disposed to be two-dimensionally spaced apart from each other. Top surfaces of the buried contact patterns BC may be located at a lower level than those of the bit line structures BLS.

A bottom surface of the buried contact pattern BC may be located at a level that is lower than the top surface of the semiconductor substrate 100 and is higher than the bottom surface of the bit line contact pattern DC. In addition, the buried contact pattern BC may be electrically disconnected from the bit line contact pattern DC by the bit line contact spacer DCS.

Fence patterns (not shown) may be disposed between the bit line structures BLS to be spaced apart from each other in the second direction D2. The fence patterns may be disposed between the buried contact patterns BC adjacent to each other in the second direction D2. The fence patterns may overlap the word lines WL in a plan view. The fence patterns may include an insulating material such as silicon nitride.

A landing pad LP may be disposed on the buried contact pattern BC, respectively. The landing pad LP may be electrically connected to the buried contact pattern BC.

In embodiments, the landing pad LP may include a lower portion formed between the bit line structures BLS and an upper portion extending from the lower portion onto portions of the bit line structures BLS. That is, the upper portion of the landing pad LP may overlap portions of the bit line structures BLS in a plan view. The upper portion of the landing pad LP may cover a top surface of the hard mask pattern HM of the bit line structure BLS and may have a width greater than that of the buried contact pattern BC. In other words, the width of the upper portion of the landing pad LP may be greater than a distance between the bit line structures BLS or a width of the bit line structure BLS. Since the upper portion of the landing pad LP extends onto the bit line structures BLS, the top surface of the landing pad LP may have an increased area.

In embodiments, the top of the landing pad LP may have an elliptical shape with a long axis and a short axis in a plan view. The upper portion of the landing pad LP may have the long axis along the inclined direction with respect to the first direction D1 and the second direction D2. In embodiments, the upper portion of the landing pad LP may have a rounded diamond shape, a rounded trapezoidal shape, or a rounded tetragonal shape.

A pad insulating pattern PIP may be provided to fill a space between the upper portions of the landing pads LP. The pad insulating pattern PIP may have a rounded bottom surface, and the bottom surface of the pad insulating pattern PIP may be in contact with portions of the bit line spacers. A top surface of the pad insulating pattern PIP may be coplanar with the top surface of the landing pad LP. The pad insulating pattern PIP may include a silicon oxide layer, a silicon nitride layer, and/or a silicon oxynitride layer. The pad insulating pattern PIP may be formed of a single layer or multi-layer.

According to embodiments, a data storage pattern DS may be disposed on the landing pad LP, respectively. The data storage pattern DS may be electrically connected to the second impurity region 1b through the landing pad LP and the buried contact pattern BC, respectively. The data storage pattern DS may be disposed to be offset from the landing pad LP and may be in contact with a portion of the landing pad LP. For example, the data storage pattern DS may be disposed to form a honeycomb shape or a zigzag shape, in a plan view.

For example, the data storage pattern DS may be a capacitor and may include lower and upper electrodes and a dielectric layer interposed therebetween. Alternatively, the data storage pattern DS may be a variable resistance pattern whose resistance may be switched to one of two resistance states by an electrical pulse applied to a memory element. For example, the data storage pattern DS may include phase-change materials, perovskite compounds, transition metal oxides, magnetic materials, ferromagnetic materials, or antiferromagnetic materials, whose crystal state can be changed depending on an amount of current applied thereto.

In the peripheral circuit region PCR, a first transistor having a first threshold voltage may be provided on the first region 10, and a second transistor having a second threshold voltage may be provided on the second region 20. The first threshold voltage and the second threshold voltage may be different from each other.

A device isolation layer 101 may define a first active region ACT1 on the first region 10 and may define a second active region ACT2 on the second region 20.

A first gate structure GS1 may be disposed on the first active region ACT1, and a first source/drain region SD1 may be provided in the semiconductor substrate 100 on both sides of the first gate structure GS1, respectively. The first source/drain region SD1 may be a portion of the semiconductor that are doped with impurities of a first conductivity type (e.g., n-type).

A second gate structure GS2 may be disposed on the semiconductor substrate 100 on the second active region ACT2, and a second source/drain region SD2 may be provided in the semiconductor substrate 100 at both sides of the second gate structure GS2, respectively. The second source/drain region SD2 may be a portion of the semiconductor that are doped with impurities of a second conductivity type (e.g., p-type).

As described refer to FIGS. 1 and 2, the first gate structure GS1 may include an insulating pattern 130, a first interface pattern IL1, a first high-k dielectric pattern HK1, a first metal pattern MP1, a first conductive structure CST1, and a first hard mask pattern HM1.

As described refer to FIGS. 1 and 2, the second gate structure GS2 may include a second interface pattern IL2, a second high-k dielectric pattern HK2, a second metal pattern MP2, a second conductive structure CST2, and a second hard mask pattern HM2.

A semiconductor layer 110 may be disposed between the second active region ACT2 and the second gate structure GS2.

Referring to FIGS. 16 and 3A, as described above, the first source/drain region SD1 may include a first lower portion SD1_L and a first upper portion SD1_U. The first lower portion SD1_L may be in contact with the device isolation layer 101, and the first upper portion SD1_U may be spaced apart from the device isolation layer 101.

The first lower portion SD1_L of the first source/drain region SD1 may have a first sidewall S1 facing the second source/drain regions SD2.

The first upper portion SD1_U of the first source/drain region SD1 may have a second sidewall S2 connected with the first sidewall S1. The second sidewall S2 may be inclined with the first sidewall S1. The second sidewall S2 may be spaced apart from the device isolation layer 101.

The first upper portion SD1_U of the first source/drain region SD1 may further include a third sidewall S3 connected to the second sidewall S2. The third sidewall S3 may be inclined with the second sidewall S2. The third sidewall S3 may be connected to a top surface of the first source/drain region SD1.

One sidewall SD2_S1 of the second source/drain region SD2 may face the first sidewall S1 and the third sidewall S3 of the first source/drain regions SD1. For example, the one sidewall SD2_S1 of the second source/drain region SD2 may be flat.

According to embodiments of the inventive concept, during a process of manufacturing first and second transistors having different threshold voltages on first and second active regions, respectively, an insulating layer on the first active region may be formed through an oxidation process. The insulating layer formed through the oxidation process may have a more uniform thickness than that formed through a deposition process. The insulating layer formed through the oxidation process may have a relatively harder (or denser) film property than that of the insulating layer formed through the deposition process.

That is, the overall quality of the insulating layer can be improved. Therefore, the reliability of the insulating layer 130 may be improved in a subsequent process such as etching, and leakage current in transistor may be reduced. Furthermore, the electrical characteristics and reliability of the transistor can be improved.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a semiconductor substrate including a first active region and a second active region;
a first source/drain region provided in the first active region;
a second source/drain region provided in the second active region;
a first gate structure disposed on the first active region;
a semiconductor layer having a lattice constant different from a lattice constant of the second active region of the semiconductor substrate and disposed on the second active region; and
a second gate structure disposed on the semiconductor layer,
wherein the first source/drain region includes a first lower portion and a first upper portion disposed on the first lower portion,
wherein the first lower portion includes a first sidewall facing the second source/drain region, and
wherein the first upper portion includes a second sidewall connected to the first sidewall of the first lower portion and inclined with the first sidewall.

2. The semiconductor device of claim 1, wherein the semiconductor layer includes silicon-germanium (SiGe), and
wherein the semiconductor layer is not provided on the first active region.

3. The semiconductor device of claim 1, wherein the first upper portion further includes a third sidewall connected to the second sidewall and inclined with the second sidewall.

4. The semiconductor device of claim 1, wherein the second sidewall of the first upper portion has a rounded shape.

5. The semiconductor device of claim 1, further comprising:
a device isolation layer defining between the first active region and the second active region,
wherein the device isolation layer covers the first sidewall and is spaced apart from the second sidewall.

6. The semiconductor device of claim 1, wherein the second source/drain region has a flat sidewall facing the first source/drain regions.

7. The semiconductor device of claim 1,
wherein the first gate structure comprises:
an insulating pattern disposed on the first active region;
a first interface pattern disposed on the insulating pattern;
a first high-k dielectric pattern disposed on the first interface pattern; and
a first metal pattern disposed on the first interface pattern,
wherein the second gate structure comprises:
a second interface pattern disposed on the semiconductor layer;
a second high-k dielectric pattern disposed on the second interface pattern; and
a second metal pattern disposed on the second interface pattern.

8. The semiconductor device of claim 7, wherein a vertical distance between the first high-k dielectric pattern and the first active region is greater than a vertical distance between the second high-k dielectric pattern and the semiconductor layer.

9. The semiconductor device of claim 7, wherein a work function of the first metal pattern is smaller than a work function of the second metal pattern.

10. The semiconductor device of claim 7, wherein the second metal pattern includes a lanthanoid material and aluminum.

11. The semiconductor device of claim 1, wherein the first source/drain region comprises a first conductivity type material, and
wherein the second source/drain region comprises a second conductivity type material different from the first conductivity type material.

12. A semiconductor device, comprising:
a semiconductor substrate including a first active region, a second active region, and a third active region sequentially disposed along a first direction;
a first source/drain region provided in the first active region;
a second source/drain region provided in the second active region;
a third source/drain region provided in the third active region;
a first gate structure disposed on the first active region;
a second gate structure disposed on the second active region;
a third gate structure disposed on the third active region; and
a semiconductor layer disposed between the second active region and the second gate structure,
wherein the first source/drain region comprises a first lower portion and a first upper portion disposed on the first lower portion,
wherein the third source/drain region comprises a second lower portion and a second upper portion disposed on the second lower portion,
wherein a sidewall of the first upper portion is inclined with a sidewall of the first lower portion,
wherein a sidewall of the second upper portion is inclined with a sidewall of the second lower portion, and
wherein the semiconductor layer includes silicon-germanium (SiGe).

13. The semiconductor device of claim 12, wherein the semiconductor layer is not provided on the first active region and the third active region.

14. The semiconductor device of claim 12, further comprising:
a device isolation layer defining between the first active region and the second active region, and disposed between the second active region and the third active region,
wherein the device isolation layer covers the sidewall of the first lower portion, and is spaced apart from the sidewall of the first upper portion; and
wherein the device isolation layer covers the sidewall of the second lower portion and is spaced apart from the sidewall of the second upper portion.

15. The semiconductor device of claim 12, wherein the second source/drain region has a first flat sidewall and a second flat sidewall facing the first source/drain region and third source/drain region, respectively.

16. The semiconductor device of claim 12,
wherein the first gate structure comprises:
an insulating pattern disposed on the first active region;
a first interface pattern disposed on the insulating pattern;
a first high-k dielectric pattern disposed on the first interface pattern; and
a first metal pattern disposed on the first interface pattern,
wherein the second gate structure comprises:
a second interface pattern disposed on the semiconductor layer;
a second high-k dielectric pattern disposed on the second interface pattern; and
a second metal pattern disposed on the second interface pattern,
wherein the third gate structure comprises:
a third interface pattern disposed on the third active region;
a third high-k dielectric pattern disposed on the third interface pattern; and
a third metal pattern disposed on the third interface pattern.

17. The semiconductor device of claim 16, wherein a vertical distance between the first high-k dielectric pattern and the first active region is greater than a vertical distance between the second high-k dielectric pattern and the semiconductor layer.

18. The semiconductor device of claim 16, wherein a vertical distance between the second high-k dielectric pattern and the semiconductor layer is substantially the same as a vertical distance between the third high-k dielectric pattern and the third active region.

19. A semiconductor device, comprising:
a semiconductor substrate including a cell array region and a peripheral circuit region, the peripheral circuit region including a first active region and a second active region;
a device isolation layer defining a cell active region disposed on the cell array region, the first active region, and the second active region;
a bit line structure crossing the cell active region disposed on the cell array region;
a first source/drain region provided in the first active region;
a second source/drain region provided in the second active region;
a first gate structure disposed on the first active region;
a semiconductor layer having a lattice constant different from a lattice constant of the semiconductor substrate and disposed on the second active region; and
a second gate structure disposed on the semiconductor layer,
wherein the first source/drain region comprises a first lower portion and a first upper portion disposed on the first lower portion,
wherein the first lower portion includes a first sidewall facing the second source/drain region, and
wherein the first upper portion includes a second sidewall connected to the first sidewall of the first lower portion and inclined with the first sidewall.

20. The semiconductor device of claim 19, wherein the device isolation layer covers the first sidewall and is spaced apart from the second sidewall.
